(19) United States
(12) Patent Application Publication
(10) Pub. No.: US 2010/0275980 A1
(43) Pub. Date: Nov. 4, 2010

(54) PHOTOVOLTAIC MODULES HAVING REFLECTIVE ADHESIVE FILMS

(75) Inventors: Andreas Karpinski, Odenthal (DE); Uwe Keller, Bonn (DE); Michael Henkel, Troisdorf (DE)

Correspondence Address: BROOKS KUSHMAN P.C., 1000 TOWN CENTER, TWENTY-SECOND FLOOR, SOUTHFIELD, MI, 48075, US

(73) Assignee: KURARAY EUROPE GMBH, Frankfurt am Main (DE)

(21) Appl. No.: 12/746,385

(22) PCT Filed: Dec. 8, 2008
(86) PCT No.: PCT/EP2008/067041

§ 371 Date: Jun. 4, 2010

(30) Foreign Application Priority Data
Dec. 7, 2007 (DE) 10 2007 055 733.9

(51) Int. Cl. H01L 31/04

(52) U.S. Cl. 136/252

(57) ABSTRACT

Photovoltaic modules with increased performance are obtained by positioning a reflective polyvinyl adhesive film below the photosensitive layer, this adhesive layer containing a plasticizer of low polarity expressed by 100×O/(C+H)≦9.4.

### TECHNICAL AREA

The invention relates to the production of photovoltaic modules using adhesive films that reflect sunlight, particularly films containing plasticisers and having a base of polyvinyl acetal.

### RELATED ART

Photovoltaic modules include a photosensitive semiconductor layer that is provided with a transparent cover to protect the semiconductor layer from external influences. Monocrystalline solar cells or polycrystalline, thin semiconductor layers on a substrate may be used as the photosensitive semiconductor layer. Thin-film solar modules consist of a photosensitive semiconductor layer that is applied to a usually transparent plate, for example by vapour deposition, gas phase separation, sputtering or wet separation.

Both systems are frequently laminated with a transparent adhesive between a pane of glass and a rigid rear cover plate, made for example from glass or plastics.

The transparent adhesive must completely enclose the photosensitive semiconductor layer and its electrical connection wires, it must also be UV-stable and insensitive to moisture, and must be totally bubble-free after the lamination process.

Substances that are frequently used as transparent adhesives are hardening cast resins or cross-linkable systems based on ethylene vinyl acetate (EVA) such as are disclosed for example in DE 41 22 721 C1 or DE 41 28 766 A1.

An alternative to hardening adhesive systems is the use of polyvinyl acetal-based plasticising films such as polyvinyl butyral (PVB), which is known from composite glass manufacturing. The solar cell units are covered with one or more PVB films, which are then bonded with the desired protective material under high pressure and temperature to form a laminate.

Methods for producing solar modules using PVB films are known, for example, from patent nos. DE 40 26 165 C2, DE 42 278 60 A1, DE 29 237 70 C2, de 35 38 986 c2 OR U.S. Pat. No. 4,321,418. The use of PVB films as composite safety glazing elements in solar modules is disclosed for example in DE 20 302 045 U1, EP 1617487, and DE 35 389 86 C2.

Some of the sunlight that falls on the photosensitive layer of the solar modules passes right through them and is wasted for the purposes of conversion into electrical energy. In order to improve the solar modules' efficiency, they are often equipped with a reflective back side. For this, either a mirror layer or reflective pigments in the form of an additional layer for example are applied to the modules. This method is costly, because it entails inserting an additional layer in the solar module. Moreover, the electrically conductive mirror layers or reflective pigments must not come into contact with the photosensitive layer, because this leads to the danger of short circuits.

An increasingly important feature of adhesive films for photovoltaic modules is their electrical conductivity, because photosensitive semiconductor layers are becoming more and more efficient, even as they are being used in humid environmental conditions, and as a result the insulating capability of the film is subject to more and more stringent requirements.

Charge losses or even short circuits in the semiconductor layer must be avoided, even in the face of extreme weather conditions such as tropical temperatures, high atmospheric humidity, or strong UV radiation, throughout the entire operating life of the module. Photovoltaic modules are subjected to many tests in accordance with IEC 61215 (damp heat test, wet leakage current test) designed to reduce the leakage currents of the modules. In order to achieve this, the adhesive films must possess the highest possible specific resistance.

### OBJECT

The object of the present invention is therefore to suggest a simple construction method for furnishing photovoltaic modules with a reflective layer in order to increase their output capacity.

As was noted earlier, many of the known photovoltaic modules are furnished with adhesive films. Surprisingly, it was found that it is quite simple to furnish these adhesive films with reflective properties.

### BRIEF DESCRIPTION OF THE INVENTION

Accordingly, the object of the present invention are photovoltaic modules that include

a) a transparent front cover

b) one or more photosensitive semiconductor layers

c) at least one adhesive film

d) a rear cover

wherein at least one adhesive film is finished as reflective.

The adhesive film is finished to reflect diffusely, so that some of the light that passes through the photosensitive semiconductor layer is reflected back onto it, thereby increasing the module's effectiveness.

A critical factor in the efficiency improvement of the photovoltaic modules according to the invention is the coefficient of radiant reflection or the reflective properties of the reflective adhesive film. As is indicated in the examples, this is determined on films that have been flattened (that is to say roll-smoothed) in accordance with DIN EN 410, and is at least 15% or 25%, at least 30% however, preferably at least 50%, and particularly at least 70%.

Such measurements may be carried out on a “Lambda 950” UV/VIS spectrophotometer manufactured by Perkin-Elmer. According to DIN EN 410, the coefficient of radiant reflection is determined in the 300-2500 nm wavelength range.

Photovoltaic modules having a design principle of glass/photosensitive semiconductor layer/adhesive film according to the invention/glass demonstrate a performance improvement of approximately 0.5 to 5% over a photovoltaic module constructed in the same way without reflective adhesive film (that is to say, having an adhesive film of the same composition but without reflective properties.

With the reflective adhesive film implemented in accordance with the invention, the surface area of the photovoltaic modules having the same output may be reduced by an amount equivalent to the efficiency improvement.

The adhesive film preferably contains reflective pigments or a reflective intermediate layer. For the purposes of the present invention, the term reflection is understood to mean reflection of the radiation that is able to be converted into electrical energy for the photosensitive semiconductor layer, which is usually the radiation in the UV range, the wavelength range of visible light and the near infrared range.

The “white pigments”, that is to say pigments having a refraction index higher than 1.8, are particularly suitable for use as reflective pigments. These include one or more white pigments from the group titanium dioxide, zinc baryta white, barium sulphate, zinc oxide, zinc sulphide, and lead carbonate. Alternatively or additionally, one or more metals of the group Al, Zn, Cr or Ti may also be used as reflective pigments. Silicon dioxide is not suitable for use according to the invention.

For the purposes of the invention, these pigments may also be separated on a substrate material that is introduced into the adhesive film. Metal particles or particles coated with metal may equally well be used as reflective pigments.

The intermediate layer may be laminated in between two adhesive films, so that the desired adhesive effect is achieved on the outer sides thereof. A polymer film coated with metal, for example a PET film sputtered with Al, Zn, Cr, or Ti among others may serve as the reflective intermediate layer. Films of such kind are known from automobile production and are used to reduce the amount of sunlight that shines into the vehicle interior. The film preferably reflects incident light diffusely.

Alternatively, the intermediate layer may consist of at least one unpigmented and at least one pigmented sublayer. Thus for example, the sublayers on the outside may have an adhesive effect, while the inner sublayer, which contains the reflective pigments, may serve the purpose of reflecting the light rays.

Films that are made up of multiple sublayers may be produced in a single process step by joining prefabricated sublayers or by coextrusion of the sublayers.

The proportion of reflective pigments in the reflective adhesive film or on the reflectively coated polymer film is preferably 0.1 to 25% by weight, particularly 1 to 20% by weight, and particularly preferably 1 to 10% by weight. If the adhesive film is constructed from unpigmented and pigmented sublayers, this value is relative to the film as a whole, which means that higher concentrations may be used in the pigment-containing sublayer depending on the thickness distribution.

In the situation in which the intermediate layer consists of at least one unpigmented and at least one pigmented sublayer, these sublayers may each contain a different or an identical compound or polymer materials.

Any of the known composite glazing materials, such as PVC, Geniomer (polydimethylsiloxane/urea copolymer), silicones, polyurethane, ethylene/vinyl acetate, epoxy casting resins, ionomers (SentryGlass plus), polyolefins, or particularly polyvinyl acetals or polyinyl butyrals containing plasticisers may be used as the material for the adhesive layer and sublayers.

Films that include polyvinyl acetal with a plasticiser preferably contain uncrosslinked polyvinyl butyral (PVB), which is obtained by acetalisation of polyvinyl alcohol with butyraldehyde.

It is also possible to use crosslinked polyvinyl acetals, particularly crosslinked polyvinyl butyral (PVB). Suitable crosslinked polyvinyl acetals are described for example in EP 1527107 B1 and WO 2004/063231 A1 (thermal autocrosslinking of polyvinyl acetals containing carboxy groups), EP 1606325 A1 (polyvinyl acetals crosslinked with polyaldehydes) and WO 03/020776 A1 (polyvinyl acetals crosslinked with glyoxylic acid). The disclosures of these patent applications are included herewith by reference in their entirety.

It is also possible to perform the acetalisation with other or additional aldehydes having 5-10 carbon atoms (valeraldehyde, for example).

In the context of the present invention, terpolymers from hydrolysed vinyl acetate/ethylene copolymers may also be used as the polyvinyl alcohol. These compounds are usually more than 99% hydrolysed and contain 1 to 10 ethylene-based units by weight (for example of type “Exceval” by Kuraray Europe GmbH).

Besides the acetal units, polyvinyl acetals also contain units resulting from vinyl acetate and vinyl alcohol. The polyvinyl acetals used in accordance with the invention preferably include a polyvinyl alcohol component of less than 21% by weight, less than 18% by weight, less than 16% by weight, or preferably less than 14% by weight. The polyvinyl alcohol component should not be less than 12% by weight.

The polyvinyl acetate component is preferably less than 5% by weight, preferably less than 3% by weight, and particularly less than 2% by weight. The degree of acetalisation may be calculated arithmetically from the polyvinyl alcohol component and the residual acetate content.

The films used according to the invention preferably have a specific resistance of at least 1E+11 ohm*cm, preferably at least 5E+11 ohm*cm, preferably 1E+12 ohm*cm, preferably 5E+12 ohm*cm, preferably 1E+13, preferably 5E+13 ohm*cm, preferably 1E+14 ohm*cm in ambient humidity of 85% r.h. at 23° C.

The films used according to the invention, particularly those based on polyvinyl acetal containing plasticiser, preferably have a plasticiser content of not more than 40% by weight, 35% by weight, 32% by weight, 30% by weight, 28% by weight, 26% by weight, 24% by weight, 22% by weight, 20% by weight, 18% by weight, 16% by weight, wherein the plasticiser content should not be less than 15% by weight (relative to the total film formulation in each case), otherwise its ability to be processed is impaired. Films or photovoltaic modules according to the invention may contain one or more plasticisers.

Plasticisers that are generally suitable for the films based on polyvinyl acetals and used according to the invention are selected from the following groups:
esters of polyvalent aliphatic or aromatic acids, for example dialkyl adipates such as dihexyl adipate, dioctyl adipate, hexyl cyclohexyl adipate, mixtures of heptyl or nonyl adipates, diisononyl adipate, heptylnonyl adipate and esters of adipic acid with cycloaliphatic ester alcohols or with ester alcohols containing ether compounds, dialkyl sebacates such as dibutyl sebacate, and esters of sebacic acid having cycloaliphatic ester alcohols or ester alcohols containing ether compounds, esters of phthalic acid such as butylbenzyl phthalate or bis-2-butoxyethyl phthalate
esters or ethers of polyvalent aliphatic or aromatic alcohols or oligoether glycols having one or more unbranched or branched aliphatic or aromatic substituents, such as esters of di-, tri-, or tetraglycols with linear or branched aliphatic or cycloaliphatic carboxylic acids; examples of the latter group may include diethylene glycol-bis-(2-ethylhexanoate), triethylene glycol-bis-(2-ethylhexanoate), triethylene glycol-bis-(2-ethylbutanoate), tetraethylene glycol-bis-n-heptanoate, triethylene glycol-bis-n-heptanoate, triethylene glycol-bis-n-hexanoate, tetraethylene glycol dimethylether and/or dipropylene glycol benzoate
phosphates having aliphatic or aromatic ester alcohols such as tris(2-ethylhexyl)phosphate (TOF), triethyl phosphate, diphenyl-2-ethylhexyl phosphate, and/or tricresyl phosphate
esters of citric acid, succinic acid, and/or fumaric acid.

One or more compounds selected from the group of di-2-ethylhexyl sebacate (DOS), di-2-ethylhexyl adipate (DOA), dihexyl adipate (DHA), dibutyl sebacate (DBS), triethylene glycol-bis-n-heptanoate (3G7), tetraethylene glycol-bis-n-heptanoate (4G7), triethylene glycol-bis-2-ethyl hexanoate (3GO and 3G8), tetraethylene glycol-bis-n-2-ethyl hexanoate (4GO and 4G8), di-2-butoxyethyl adipate (DBEA), di-2-butoxyethoxyethyl adipate (DBEEA), di-2-butoxyethyl sebacate (DBES), di-2-ethylhexyl phthalate (DOP), di-isononyl phthalate (DINP), triethylene glycol-bis-isononanoate, triethylene glycol-bis-2-propyl hexanoate, tris(2-ethylhexyl)phosphate (TOF), 1,2,-cyclohexane dicarboxylic acid diisononyl ester (DINCH), and dipropylene glycol benzoate have been found to be highly suitable plasticisers for the polyvinyl acetal-based films used according to the invention.

Plasticisers having polarity that is expressed by the formula 100×O/(C+H) is less than/equal to 9.4, wherein O, C and H stand for the number of oxygen, carbon, and hydrogen atoms in the respective molecule, have proven to be especially suitable plasticisers for the polyvinyl acetal-based films used according to the invention. The following chart lists plasticisers that are usable according to the invention together with their polarity values according to the formula 100×O/(C+H).

| | | 100 × O/ |
|---|---|---|
| Name | Abbreviation | (C + H) |
| Di-2-ethylhexyl sebacate | (DOS) | 5.3 |
| 1,2,-cyclohexane | (DINCH) | 5.4 |
| dicarboxylic acid | | |
| diisononyl ester | | |
| Di-2-ethylhexyl adipate | (DOA) | 6.3 |
| Di-2-ethylhexyl phthalate | (DOP) | 6.5 |
| Dihexyl adipate | (DHA) | 7.7 |
| Dibutyl sebacate | (DBS) | 7.7 |
| Triethylene glycol-bis-2- | | 8.6 |
| propyl hexanoate | | |
| Triethylene glycol-bis-i- | | 8.6 |
| nonanoate | | |
| Di-2-butoxyethyl sebacate | (DBES) | 9.4 |
| Triethylene glycol-bis-2- | (3G8) | 9.4 |
| ethyl hexanoate | | |

The adhesion of polyvinyl acetal films to glass is usually adjusted by adding adhesion regulators such as the alkaline or earth alkali salts of organic acids disclosed for example in WO 03/033583 A1. Potassium acetate and/or magnesium acetate have proven to be particularly suitable. Polyvinyl acetals often also contain alkaline and/or earth alkali salts of inorganic acids such as sodium chloride as a result of the manufacturing process.

Since salts also affect specific resistance, it is advisable for the polyvinyl acetal-based films containing plasticisers to include fewer than 50 ppm metal ions, preferably fewer than 30 ppm, and particularly fewer than 20 ppm. This may be achieved by washing the polyvinyl acetal appropriately, and by using particularly effective anti-adhesive agents, such as the magnesium, calcium, and/or zinc salts of organic acids (for example acetates) that are known to one skilled in the art.

Ion mobility, which may be dependent on the water content in the film, and thus also specific resistance, may also be influenced by adding pyrogenic silicic acid. The polyvinyl acetal-based films containing plasticisers preferably include 0.001 to 15% by weight, preferably 2 to 5% by weight pyrogenic SiO₂.

The basic production and composition of polyvinyl acetal-based films is described for example in EP 185 863 B1, EP 1 118 258 B1, WO 02/102591 A1, EP 1 118 258 B1 or EP 387 148 B1.

The photovoltaic modules are laminated by melting the films in such manner that the photosensitive semiconductor layer is included in the films without bubbles or streaks.

The overall thickness of the adhesive films is usually 0.38, 0.51, 0.76, 1.14, 1.52 or 2.28 mm.

Films used according to the invention fill out the cavities on the photosensitive semiconductor layers and the electrical connections thereof during the lamination process.

The transparent front cover is usually made from glass or PMMA. The rear cover of the photovoltaic module according to the invention may consist of glass, plastic or metal, or composites thereof, wherein at least one of the substrates may be transparent. It is also possible to design one or both covers in the form of composite glazing (that is to say as a laminate consisting of at least two panes of glass and at least one PVB film) or a insulating glazing with a gas-filled cavity. Of course, a combination of these constructions may also be implemented.

The photosensitive semiconductor layers used in the modules do not have to possess any special properties. Monocrystalline, polycrystalline or amorphous systems may be used.

If thin film solar modules according to the invention are produced, the photosensitive semiconductor layers are usually superimposed directly on the transparent front cover and joined adhesively to the rear cover by at least one adhesive film according to the invention.

When crystalline or supported modules are manufactured, the solar modules must be encapsulated by adhesive films, that is to say the photosensitive semiconductor layers b) are joined adhesively to the transparent front cover a) by at least one non-reflective adhesive film, and to the rear cover d) by at least one adhesive film according to the invention. These films preferably have the same composition as reflective adhesive films except for the reflective pigments.

Lamination of the layer element obtained in this way may be carried out by processes familiar to one skilled in the art, with and without prior production of a preliminary composite.

Autoclaving processes are conducted for approximately 2 hours under elevated pressure of approximately 10 to 15 bar and at temperatures from 130 to 145° C. Vacuum bag or vacuum ring methods such as are described in EP 1 235 683 B1 operate at about 200 mbar and 130 to 145° C.

Vacuum laminators are preferably used to produce the photovoltaic modules according to the invention. These consist of a chamber that is able to be heated and evacuated, in which composite glazing elements may be laminated within 30-60 minutes. Partial vacuums from 0.01 to 300 mbar and temperatures from 100 to 200° C., particularly 130-160° C. have proven effective in practice.

Alternatively, a layer element that has been combined as described above may be pressed between at least one pair of rollers at a temperature of 60 to 150° C. to form a module according to the invention. Such systems for manufacturing composite glazing elements are known and are normally equipped with at least one heating tunnel before and/or after the first press plant in systems with two press plants.

Photovoltaic modules according to the invention may be used as building façade elements, roof surfaces, conservatory covers, noise barriers, balcony or parapet elements, or as components in window surfaces.

### Measurement Methods:

The specific contact resistance of the film is measured in accordance with DIN IEC 60093 at a defined temperature and ambient humidity (23° C. and 85% relative humidity) after the film has been conditioned in this atmosphere for at least 24 hours. A type 302 132 plate electrode produced by Fetronic GmbH and an ISO-Digi 5 kV resistance meter produced by Amprobe were used to carry out the measurement. The test voltage was 2.5 kV, the wait time after application of the test voltage before the measurement was taken was 60 seconds. To ensure that adequate contact is guaranteed between the flat plates of the measurement electrode and the film, the surface roughness R_{z} of the film should not be greater than 10 μm when measured according to DIN EN ISO 4287, which means that it may be necessary to smooth the original surface of the PVB film by thermal recoining.

The polyvinyl alcohol and polyvinyl alcohol acetate content of the polyvinyl acetals was determined in accordance with ASTM D 1396-92. The water or moisture content of the films is determined by the Karl Fischer method.

In order to measure its reflective properties, the surface of the adhesive films, which may originally have been roughened, was smoothed by heating between two sheets of PET film. Of course, this treatment step may be omitted for adhesive films that already have a smooth surface, or it may be advisable to smooth the surface between sheets of a substance other than PET, if this adheres too strongly to the adhesive film and is difficult to take off. After the PET film was removed, the reflection of light in the 380-780 nm wavelength by this side of the adhesive film was determined in accordance with DIN EN 410 using a Hitachi U-3410 spectrophotometer at an angle of 8°.

For the examples listed, the degree of radiated reflection of a smooth or smoothed side of the adhesive film was determined in a wavelength range from 300-2500 nm using a “Lambda 950” UV/VIS spectrophotometer produced by Perkin-Elmer. Since the measurement is to be carried out on a flat sample, the adhesive film may be secured to a transparent support, for example a pane of glass, in order to take the measurement.

### EXAMPLES

Polyvinyl butyral films containing plasticiser and with a reflective pigment were tested to determine their suitability for use as reflective film in photovoltaic modules.

Accordingly, a film of the type “Trosifol Colour W17” (thickness 0.38 mm), available commercially from Kuraray Europe GmbH and containing about 1% by weight TiO₂, was shown to have a light reflectivity as described above of 68.7%. A photovoltaic module produced with this film and having a structure of glass/photosensitive semiconductor layer/“Trosifol Colour W17”/glass returned an output 0.75% better than a similar module using standard PVB film with no pigment.

Single-layer of multiple-layer films based on plasticiser-containing polyvinyl butyral and with the compounds listed in the tables below were pigmented homogeneously or partially with titanium dioxide. The three-layer films were obtained by coextrusion using a feedblock distributor. In the case of the three-layer films, only the inside layer is furnished with titanium dioxide as the reflective pigment, whereas the outer layers essentially consist only of PVB and plasticiser, and are transparent. In both cases, adhesive films constructed with single or multiple layers, the white or metallically reflective pigment may first be suspended in the plasticiser and then extruded together with the PVB resin to form the film or film layer, or it may be fed directly into the intake area of the extruder in measured quantities as a solid. For the examples, the pigments were fed directly into the extruder in measured quantities while it was running.

Photovoltaic modules manufactures with this film, having a construction of glass/photosensitive semiconductor layer/reflective film/glass returned an output 0.7-1.5% better than an identically constructed module with a film of the same composition but without the pigment.

The films consisted of plasticised polyvinyl butyral (PVB) with the indicated content by percentage weight of polyvinyl alcohol (PVOH) and a content of about 1% by weight polyvinyl acetate.

The following terms are also used:

HOMBITAN surface-treated rutile type TiO₂, manufacturer: Sachleben Chemie

KRONOS 2226 surface-treated rutile type TiO₂, manufacturer: Kronos Titan GmbH

KRONOS 2450 surface-treated rutile type TiO₂, manufacturer: Sachleben Chemie

1S single-layer film

3S three-layer film

* Proportion in the middle layer

| Example | 1 | 2 | 3 | 4 | 5 | 6 |
|---|---|---|---|---|---|---|
| Material type | 3S | 3S | 3S | 3S | 1S | 1S |
| Mowital (PVB): PVOH 20.0% | 76 | 76 | | | 72.5 | |
| Mowital (PVB): PVOH 14.0% | | | 74 | 74 | | 76 |
| Plasticiser 3G8 | 24 | 24 | | | 25 | |
| Plasticiser DBEA | | | | | 2.5 | |
| Plasticiser DOA | | | 26 | 26 | | |
| Plasticiser DINCH | | | | | | 24 |
| HOMBITAN (TiO2) | | | | | 2.5 | 5 |
| KRONOS 2226 (TiO2) | 7.5* | 7.5* | | | | |
| KRONOS 2450 (TiO2) | | | 7.5* | 7.5* | | |
| Total thickness in mm | 0.76 | 0.76 | 0.76 | 0.76 | 0.76 | 0.76 |
| Thickness of middle layer | 0.19 | 0.35 | 0.19 | 0.35 | | |
| in mm | | | | | | |
| Content (TiO2) in complete | 1.4 | 2.9 | 1.2 | 2.3 | 2.5 | 5 |
| film | | | | | | |
| Degree of radiated | 69% | 77% | 67% | 75% | 69% | 76% |
| reflection 300-2500 nm in | | | | | | |
| % accordance with DIN EN 410 | | | | | | |
| Contact resistance in | 2.0E+11 | 2.0E+11 | 3.5E+12 | 3.5E+12 | 1.5E+11 | 230E+13 |
| accordance with DIN IEC | | | | | | |
| 60093, air conditioned: | | | | | | |
| 23° C./85% r.h. | | | | | | |

| Example | 7 | 8 | 9 | 10 | 11 | 12 | 13 |
|---|---|---|---|---|---|---|---|
| Material type | 1S | 1S | 1S | 1S | 1S | 1S | 1S |
| Mowital (PVB): PVOH 20.0% | 72.5 | 72.5 | 72.5 | 72.5 | 72.5 | 72.5 | 72.5 |
| Mowital (PVB): PVOH 14.0% | | | | | | | |
| Plasticiser 3G8 | 25 | 25 | 25 | 25 | 25 | 25 | 25 |
| Plasticiser DBEA | 2.5 | 2.5 | 2.5 | 2.5 | 2.5 | 2.5 | 2.5 |
| Plasticiser DOA | | | | | | | |
| Plasticiser DINCH | | | | | | | |
| HOMBITAN (TiO2) | 5 | 7.5 | 1.316 | 2.63 | 5.13 | 7.5 | 10 |
| KRONOS 2226 (TiO2) | | | | | | | |
| KRONOS 2450 (TiO2) | | | | | | | |
| Total thickness in mm | 0.76 | 0.76 | 0.38 | 0.38 | 0.38 | 0.38 | 0.38 |
| Thickness of middle layer | | | | | | | |
| in mm | | | | | | | |
| Content (TiO2) in complete | 5 | 7.5 | 1.316 | 2.63 | 5.13 | 7.5 | 10 |
| film | | | | | | | |
| Degree of radiated | 75% | 80% | 64% | 71% | 78% | 80% | 82% |
| reflection 300-2500 nm in | | | | | | | |
| % accordance with DIN EN 410 | | | | | | | |
| Contact resistance in | 1.5E+11 | 1.5E+11 | 1.5E+11 | 1.5E+11 | 1.5E+11 | 1.5E+11 | 1.5E+11 |
| accordance with DIN IEC | | | | | | | |
| 60093, air conditioned: | | | | | | | |
| 23° C./85% r.h. | | | | | | | |

1.-11. (canceled)

12. Photovoltaic module laminate comprising, in order,
a) a transparent front cover
b) one or more photosensitive semiconductor layers
c) at least one adhesive film
d) a rear cover
wherein the at least one adhesive film is reflective and comprises polyvinyl acetal containing a plasticizer with a polarity that is expressed by the formula 100×O/(C+H)≦9.4, wherein O, C and H stand for the number of oxygen, carbon, and hydrogen atoms in the plasticizer molecule.

13. The photovoltaic module of claim 12, wherein the reflective adhesive film contains at least 15 weight % and at most 40 weight % plasticizer.

14. The photovoltaic module of claim 12, wherein the reflective adhesive film contains at least one plasticizer, selected from the group consisting of di-2-ethylhexyl sebacate, 1,2,-cyclohexane dicarboxylic acid diisononyl ester, di-2-ethylhexyl adipate, di-2-ethylhexyl phthalate, dihexyl adipate, dibutyl sebacate, triethylene glycol-bis-2-propyl hexanoate, triethylene glycol-bis-1-nonanoate, di-2-butoxyethyl sebacate, triethylene glycol-bis-2-ethyl hexanoate.

15. The photovoltaic module of claim 13, wherein the reflective adhesive film contains at least one plasticizer, selected from the group consisting of di-2-ethylhexyl sebacate, 1,2,-cyclohexane dicarboxylic acid diisononyl ester, di-2-ethylhexyl adipate, di-2-ethylhexyl phthalate, dihexyl adipate, dibutyl sebacate, triethylene glycol-bis-2-propyl hexanoate, triethylene glycol-bis-1-nonanoate, di-2-butoxyethyl sebacate, triethylene glycol-bis-2-ethyl hexanoate.

16. The photovoltaic module of claim 12, wherein the reflective adhesive film has a reflectivity of at least 15% in accordance with DIN EN 410.

17. The photovoltaic module of claim 12, wherein the reflective adhesive film contains reflective pigments.

18. The photovoltaic module of claim 12, wherein the reflective adhesive film contains a reflective intermediate layer.

19. The photovoltaic module of claim 18, wherein the reflective intermediate layer consists of a metal-coated polymer film.

20. The photovoltaic module of claim 12, wherein the reflective adhesive film consists of at least one unpigmented and at least one pigmented sublayer.

21. The photovoltaic module of claim 12, wherein the reflective adhesive film consists of at least one unpigmented and at least one pigmented sublayer and these sublayers are comprised of the same polymer material.

22. The photovoltaic module of claim 12, wherein one or more white pigments selected from the group consisting of titanium dioxide, zinc baryta white, barium sulphate, zinc oxide, zinc sulphide, lead carbonate, and metals from the group Al, Zn, Cr, or Ti are used as the reflective pigment.

23. The photovoltaic module of claim 12, wherein the reflective adhesive film has a specific resistance of at least 1E+11 ohmcm in ambient humidity of 85% r.h. at 23° C.

24. The photovoltaic module of claim 12, wherein the reflective adhesive film is a three layer adhesive film, each layer comprising polyvinyl butyral and plasticizer, and the middle of the three layers containing reflective pigment.
